(19) United States
(12) Patent Application Publication
(10) Pub. No.: US 2025/0089244 A1
(43) Pub. Date: Mar. 13, 2025

(54) ONE-TIME-PROGRAMMABLE MEMORY DEVICE

(71) Applicant: eMemory Technology Inc., HSINCHU (TW)

(72) Inventors: Chia-Chou LIN, Zhubei City (TW); Ping-Lung HO, Zhubei City (TW)

(73) Assignee: eMemory Technology Inc., HSINCHU (TW)

(21) Appl. No.: 18/831,000

(22) Filed: Sep. 11, 2024

Related U.S. Application Data
(60) Provisional application No. 63/537,860, filed on Sep. 12, 2023.

(51) Int. Cl. H10B 20/25

(52) U.S. Cl. CPC H10B 20/25

(57) ABSTRACT

A one-time-programmable (OTP) memory device includes an active region and a gate electrode layer. The active region includes a channel region having a channel layer and source/drain regions disposed on opposite sides of the channel region in a Y-direction. The gate electrode layer extends in an X-direction and wraps around the channel layer. A first thickness of the gate electrode layer from a first edge of a first end of the gate electrode layer to the channel layer in the X-direction is equal to a second thickness of the gate electrode layer from a second edge of a second end of the gate electrode layer to the channel layer in the X-direction. After the first end is connected to a first voltage and the second end is connected to a second voltage different to the first voltage, the first thickness is different to the second thickness.

### CROSS REFERENCE TO RELATED APPLICATIONS

This application claims the benefit of U.S. Provisional Application No. 63/537,860, filed on Sep. 12, 2023, the entirety of which is/are incorporated by reference herein.

### BACKGROUND OF THE INVENTION

### Field of the Invention

The present invention relates to a one-time-programmable (OTP) memory device, and, in particular, to an OTP memory device having a new OTP program mechanism.

### Description of the Related Art

The one-time-programmable (OTP) memory device has been developed. The OTP memory device is a one-time programmable non-volatile memory that can be programmed once. After the OTP memory cell in the OTP memory device is programmed, the storage state of the OTP memory cell is determined and the storage state of the OTP memory cell fails to be modified. Therefore, the OTP memory device is generally used for security applications, such as secure key storage, device IDs, and code storage.

However, although existing technologies for the OTP memory devices have been generally adequate for their intended purposes, they have not been entirely satisfactory in all respects.

### BRIEF SUMMARY OF THE INVENTION

The present disclosure provides a one-time-programmable (OTP) memory device. The OTP memory device includes a first active region, a first gate dielectric layer, and a first gate electrode layer. The first active region includes a first channel region having a first channel layer and first source/drain regions disposed on opposite sides of the first channel region in a Y-direction. The first source/drain regions have first source/drain features electrically connected to the first channel layer. The first gate dielectric layer wraps around the first channel layer. The first gate electrode layer extends in an X-direction and wraps around the first channel layer and the first gate dielectric layer. A first thickness of the first gate electrode layer from a first edge of a first end of the first gate electrode layer to the first channel layer in the X-direction is equal to a second thickness of the first gate electrode layer from a second edge of a second end of the first gate electrode layer to the first channel layer in the X-direction, and a logic state of the OTP memory device is at a first logic state. In a first program operation of the OTP memory device, after the first end is connected to a first voltage and the second end is connected to a second voltage different to the first voltage, the first thickness is different to the second thickness, and the logic state of the OTP memory device is at a second logic state different to the first logic state.

The present disclosure provides a one-time-programmable (OTP) memory device. The OTP memory device includes a first memory cell. The first memory cell includes a first active region and a first gate structure. The first active region includes a first channel region having a first channel layer and first source/drain regions disposed on opposite sides of the first channel region in a Y-direction. The first source/drain regions have first source/drain features electrically connected to the first channel layer. The first gate structure extends in an X-direction and engages the first active region to construct a first transistor. Before a first program operation of the OTP memory device, the first transistor has a first threshold voltage and a logic state of the OTP memory device is at a first logic state. In the first program operation of the OTP memory device, a first end of the first gate structure is connected to a first voltage and a second end of the first gate structure is connected to a second voltage different to the first voltage, such that a program current is generated along the first gate structure. A voltage difference between the first voltage and the second voltage is greater than an electromigration threshold. After the first program operation of the OTP memory device, the first transistor has a second threshold voltage different to the first threshold voltage, and the logic state of the OTP memory device is at a second logic state different to the first logic state.

### BRIEF DESCRIPTION OF THE DRAWINGS

In order to describe the manner in which the above-recited and other advantages and features of the disclosure can be obtained, a more particular description of the principles briefly described above will be rendered by reference to specific examples thereof which are illustrated in the appended drawings. Understanding that these drawings depict only exemplary aspects of the disclosure and are not therefore to be considered to be limiting of its scope, the principles herein are described and explained with additional specificity and detail through the use of the accompanying drawings.

FIG. 1 illustrates a top view (or a layout) of an OTP memory device with an OTP memory cell, in accordance with some embodiments of the present disclosure.

FIG. 2A illustrates an X-Z cross-sectional view of the OTP memory device with the OTP memory cell having a FinFET structure along a line A-A′ of FIG. 1 before the OTP memory device is programmed, in accordance with some embodiments of the present disclosure.

FIG. 2B illustrates an X-Z cross-sectional view of the OTP memory device with the OTP memory cell having the FinFET structure along the line A-A′ of FIG. 1 after the OTP memory device is programmed, in accordance with some embodiments of the present disclosure.

FIG. 2C illustrates an X-Z cross-sectional view of the OTP memory device with the OTP memory cell having the FinFET structure along the line A-A′ of FIG. 1 after the OTP memory device is programmed, in accordance with some embodiments of the present disclosure.

FIG. 3A illustrates an X-Z cross-sectional view of the OTP memory device with the OTP memory cell having a GAA structure along the line A-A′ of FIG. 1 before the OTP memory device is programmed, in accordance with some embodiments of the present disclosure.

FIG. 3B illustrates an X-Z cross-sectional view of the OTP memory device with the OTP memory cell having the GAA structure along the line A-A′ of FIG. 1 after the OTP memory device is programmed, in accordance with some embodiments of the present disclosure.

FIG. 3C illustrates an X-Z cross-sectional view of the OTP memory device with the OTP memory cell having the GAA structure along the line A-A′ of FIG. 1 after the OTP memory device is programmed, in accordance with some embodiments of the present disclosure.

FIG. 4 illustrates a top view (or a layout) of an OTP memory device with OTP memory cells, in accordance with some alternative embodiments of the present disclosure.

FIG. 5 illustrates a top view (or a layout) of an OTP memory device with an OTP memory cell, in accordance with some alternative embodiments of the present disclosure.

FIG. 6A illustrates an X-Z cross-sectional view of the OTP memory device with the OTP memory cell having FinFET structures along a line B-B′ of FIG. 5 before the OTP memory device is programmed, in accordance with some embodiments of the present disclosure.

FIG. 6B illustrates an X-Z cross-sectional view of the OTP memory device with the OTP memory cell having the FinFET structures along the line B-B′ of FIG. 5 after the OTP memory device is programmed, in accordance with some embodiments of the present disclosure.

FIG. 7A illustrates an X-Z cross-sectional view of the OTP memory device with the OTP memory cell having GAA structures along the line B-B′ of FIG. 5 before the OTP memory device is programmed, in accordance with some embodiments of the present disclosure.

FIG. 7B illustrates an X-Z cross-sectional view of the OTP memory device with the OTP memory cell having the GAA structures along the line B-B′ of FIG. 5 after the OTP memory device is programmed, in accordance with some embodiments of the present disclosure.

FIGS. 8 and 9 illustrate top views (or layouts) of OTP memory devices, in accordance with some alternative embodiments of the present disclosure.

### DETAILED DESCRIPTION OF THE INVENTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at, near, or nearly at,” or “within 3-5% of,” or “within acceptable manufacturing tolerances,” or any logical combination thereof, for example.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

The terminology used herein is for the purpose of describing particular embodiments only, and is not intended to be limiting of the invention. As used herein, the singular forms “a”, “an” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art. Furthermore terms, such as those defined in commonly used dictionaries, should be interpreted as having a meaning that is consistent with their meaning in the context of the relevant art, and will not be interpreted in an idealized or overly formal sense unless expressly so defined herein.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

FIG. 1 illustrates a top view (or a layout) of an OTP memory device 100 with an OTP memory cell 102, in accordance with some embodiments of the present disclosure. Although the OTP memory device 100 shown in FIG. 1 includes one OTP memory cell 102, it should be noted that the OTP memory device 100 may include more OTP memory cells similar to the OTP memory cell 102 arranged in rows and columns into an OTP memory array, in accordance with some embodiments.

The OTP memory cell 102 includes an active region 104 that extends lengthwise in the Y-direction. The active region 104 includes a channel region 104ch and source/drain regions 104sd. As shown in FIG. 1, the source/drain regions 104sd are disposed on opposite sides of the channel region 104ch in the Y-direction, in accordance with some embodiments. In some embodiments, the active region 104 is disposed over an N-type well (or N-Well) or a P-type well (or P-Well).

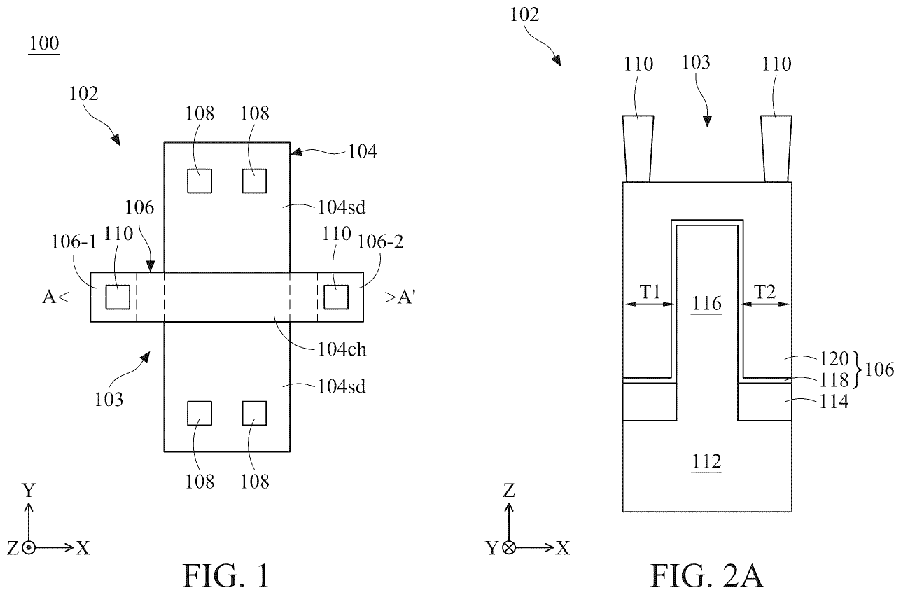

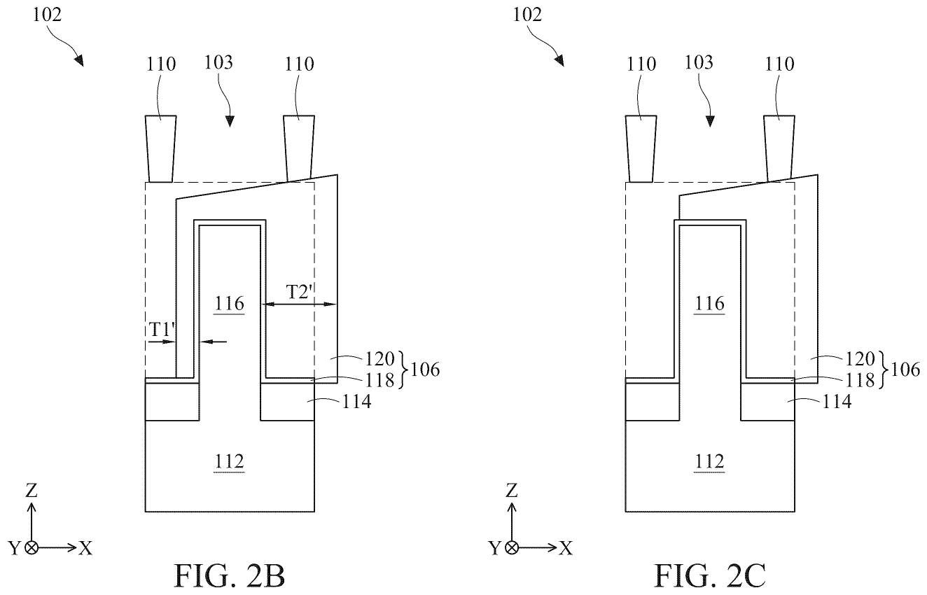

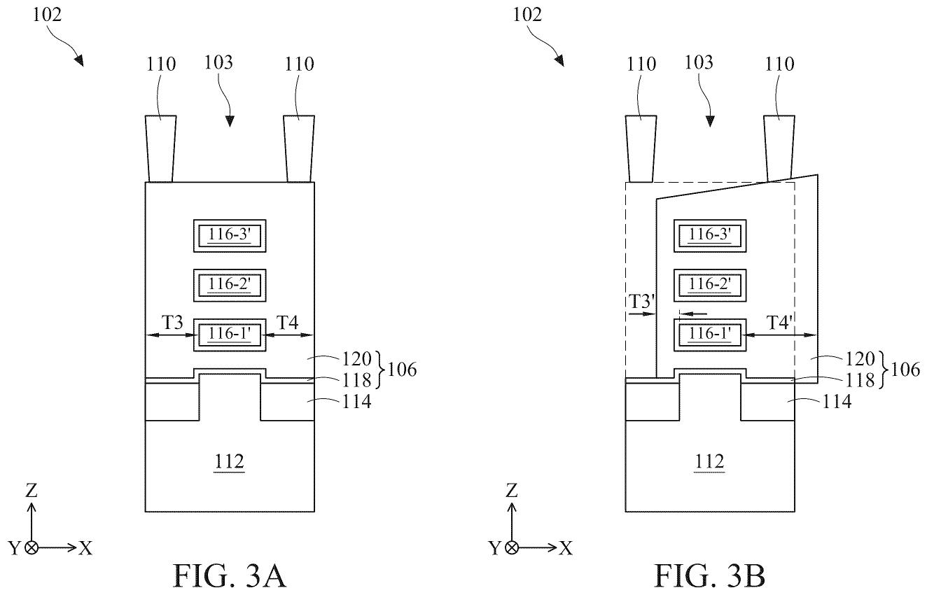

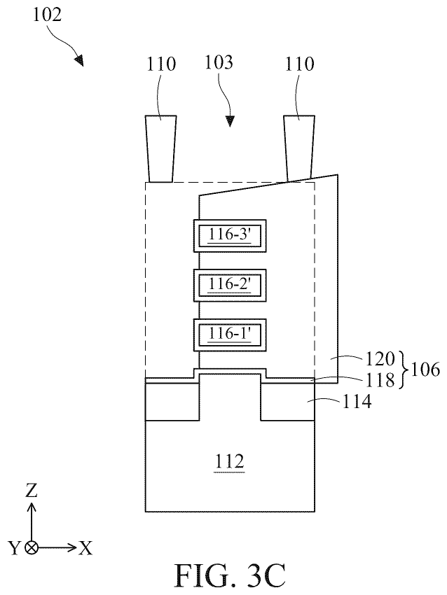

The OTP memory cell 102 further includes a gate structure 106. The gate structure 106 extends lengthwise in the X-direction perpendicular to the Y-direction to cross the active region 104, as shown in FIG. 1. The gate structure 106 is disposed over the channel region 104ch of the respective active region 104 (i.e., the channel layer(s) 116 shown in FIGS. 2A to 3C) and disposed between respective source/drain regions 104sd of the active region 104 (i.e., source/drain features in source/drain regions 104sd (not shown)). The active region 104 and the gate structure 106 are configured to provide one transistor for the OTP memory cell 102. For example, the gate structure 106 engages the active region 104 to construct a transistor 103.

The OTP memory cell 102 further includes source/drain contacts 108 and gate contacts 110. As shown in FIG. 1, the source/drain contacts 108 are disposed on the source/drain regions 104sd of the active region 104, over and electrically connected to the source/drain features (not shown) in the source/drain regions 104sd. The gate contacts 110 are disposed on and electrically connected to the gate structure 106. More specifically, the gate contacts 110 are disposed on ends 106-1 and 106-2 of the gate structure 106, as shown in FIG. 1.

The source/drain contacts 108 may each include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 108 may each include single conductive material layer or multiple conductive layers. The materials of the gate contacts 110 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

In some embodiments, the transistor 103 in the OTP memory cell 102 may also be a fin field-effect transistor (FinFET). FIG. 2A illustrates an X-Z cross-sectional view of the OTP memory device 100 with the OTP memory cell 102 having a FinFET structure along a line A-A′ of FIG. 1 before the OTP memory device 100 is programmed, in accordance with some embodiments of the present disclosure. As shown in FIG. 2A, in the case of the transistor 103 in the OTP memory cell 102 is FinFET, the OTP memory cell 102 further includes a substrate 112, over which the various features are formed, such as the gate structures 106. The substrate 112 may contains a semiconductor material, such as bulk silicon (Si).

The OTP memory cell 102 further includes isolation features 114 over the substrate 112 and isolating the active region 104 form other active regions (not shown).

As shown in FIGS. 1 and 2A, in the case of the transistor 103 in the OTP memory cell 102 is FinFET, the OTP memory cell 102 further includes a channel layer 116 in the channel region 104ch of the active region 104. The channel layer 116 is over and protrudes from the substrate 112, in accordance with some embodiments. Furthermore, the channel layer 116 extends in the Z-direction from the substrate 112. In some embodiments, the channel layer 116 is between the isolation features 114 in the X-direction, as shown in FIG. 2A. In some aspects, the isolation features 114 are around the channel layer 116. In some embodiments, the channel layer 116 is formed from the substrate 112. Although one channel layer 116 is shown in the OTP memory cell 102, there may be another appropriate number of nanostructures in the transistor 103 in the OTP memory cell 102. For example, there may be from 2 to 3 channel layers 116 in one transistor.

In some embodiments, the channel layer 116 include silicon for N-type transistors. In other embodiments, the channel layer 116 include silicon germanium for P-type transistors. In some embodiments, the channel layer 116 are all made of silicon, and the type of the transistors depend on work function metal layer wrapping around the channel layer 116.

As discussed above, the gate structure 106 engage the active region 104 to construct the transistor 103 in the OTP memory cell 102. More specifically, the gate structure 106 wraps around the channel layer 116 in the channel region 104 of the active region 104ch. The gate structure 106 has a gate dielectric layer 118 and a gate electrode layer 120. The gate dielectric layer 118 wraps around the channel layer 116 and the gate electrode layer 120 wraps around the gate dielectric layer 118 and the channel layer 116. More specifically, the gate dielectric layer 118 is on a top surface and sidewalls of the channel layer 116, as shown in FIG. 2A.

In some embodiments, the gate structure 106 further includes an interfacial layer (such as having silicon dioxide, silicon oxynitride, or other suitable materials) between the gate dielectric layer 118 and the channel layers 116. The gate dielectric layer 118 may include oxide with nitrogen doped dielectric material (initial layer) combined with metal content high-K dielectric material (K value (dielectric constant)>13). For example, gate dielectric layer 118 may include hafnium oxide (HfO₂), which has a dielectric constant in a range from about 18 to about 40. Alternatively, the gate dielectric layer 118 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layer 118 may be formed by chemical oxidation, thermal oxidation, ALD, CVD, and/or other suitable methods.

The gate electrode layer 120 is formed to wrap around the gate dielectric layer 118 and the channel layer 116, as shown in FIG. 2A. In some embodiments, the gate electrode layer 120 may include one or more N-type work function metal layers for an N-type transistor or one or more P-type work function metal layers for a P-type transistor wrapping around the channel layer 116. The material of the N-type work function metal layer and the P-type work function metal layer may be the same. In some embodiments, the material of the N-type work function metal layer and the P-type work function metal layer are different. As discussed above, the OTP memory cell 102 includes the gate contacts 110. As shown in FIG. 2A, the gate contacts 110 are over and electrically connected to the gate electrode layer 120 of the gate structure 106, in accordance with some embodiments. Furthermore, as discussed above, the gate contacts 110 are disposed on ends 106-1 and 106-2 of the gate structure 106, as shown in FIG. 1. In some embodiments, the ends 106-1 and 106-2 of the gate structure 106 may also represent the ends of the gate electrode layer 120. In other words, the gate contacts 110 are disposed on ends 106-1 and 106-2 of the gate electrode layer 120, as shown in FIGS. 1 and 2A.

As discussed above, the source/drain regions 104sd of the OTP memory cell 102 includes source/drain features. The source/drain features in the source/drain regions 104sd are disposed on opposite sides of the respective gate structure 106 in the Y-direction to form the transistor 103 in the OTP memory cell 102. The channel layer 116 connect one source/drain feature in one source/drain region 104sd to the other source/drain feature in the other source/drain region 104sd. More specifically, the source/drain features are also disposed on opposite sides of the respective channel layer 116 in the Y-direction. Therefore, the source/drain features in the source/drain regions 104sd are attached and electrically connected to the channel layer 116 in the Y-direction. The source/drain features may also be referred to as source/drains. In some embodiments, source/drain feature(s) may refer to a source or a drain, individually or collectively dependent upon the context.

The source/drain features may be formed by using epitaxial growth. In some embodiments, the source/drain features may include epitaxially-grown material selected from a group consisting of SiP, SiC, SiPC, SiAs, Si, or a combination thereof. In some embodiments, the epitaxially-grown material of the source/drain features may be doped with N-type dopants, such as phosphorus, arsenic, other N-type dopant, or a combination thereof. In some embodiments, the source/drain features doped with N-type dopants for N-type transistors may be respectively referred to as N-type features and N-type source/drain features.

In some embodiments, the source/drain features doped with P-type dopants for P-type transistors may be respectively referred to as P-type source/drain features.

As discussed above, the OTP memory device 100 with the OTP memory cell 102 having the FinFET structure shown in FIG. 2A is not programmed, in accordance with some embodiments of the present disclosure. FIG. 2B illustrates an X-Z cross-sectional view of the OTP memory device 100 with the OTP memory cell 102 having the FinFET structure along the line A-A′ of FIG. 1 after the OTP memory device 100 is programmed, in accordance with some embodiments of the present disclosure. FIG. 2C illustrates an X-Z cross-sectional view of the OTP memory device 100 with the OTP memory cell 102 having the FinFET structure along the line A-A′ of FIG. 1 after the OTP memory device 100 is programmed, in accordance with some embodiments of the present disclosure.

In order to program the OTP memory cell 102, the end 106-1 and the end 106-2 of the gate structure 106 (specifically, the gate electrode layer 120) are respectively connected to different voltages. More specifically, in a program operation of the OTP memory device 100, the end 106-1 of the gate electrode layer 120 is connected to a first voltage (may be referred to as voltage VG1 in below) and the end 106-2 of the gate electrode layer 120 is connected to a second voltage (may be referred to as voltage VG2 in below), which is different to the first voltage, such that a program current is generated along the gate structure 106 (specifically, the gate electrode layer 120). In some embodiments, the end 106-1 and the end 106-2 of the gate electrode layer 120 are respectively connected to the voltages VG1 and VG2 through the gate contacts 110 (i.e., the gate contacts 110 over the end 106-1 and the end 106-2 of the gate electrode layer 120 are connected to the voltages VG1 and VG2). In other words, the voltages VG1 and VG2 are respectively applied to the end 106-1 and the end 106-2 of the gate electrode layer 120 through the gate contacts 110 (i.e., the voltages VG1 and VG2 are applied to the gate contacts 110 over the end 106-1 and the end 106-2 of the gate electrode layer 120). Furthermore, the source/drain contacts 108 are floating during the programming of the OTP memory cell 102.

After the ends 106-1 and 106-2 are respectively connected to the voltages VG1 and VG2 and the source/drain contacts 108 are floating, the gate electrode layer 120 is changed, as shown in FIG. 2B. Compare to original gate electrode layer 120 (shown as dash line), the shape and the location of the gate electrode layer 120 are changed. Such location and shape change of the gate electrode layer 120 are caused by electromigration (i.e., a voltage difference between the voltages VG1 and VG2 is greater than an electromigration threshold (e.g., about 2V)). As discussed above, the voltages VG1 and VG2 are different and such voltage difference between the voltages VG1 and VG2 induce electromigration to make the shape and the location of the gate electrode layer 120 are changed. In some embodiments, the voltages VG1 and VG2 may be in a range from about −2V to 2V. In some embodiments, the voltage difference between the voltages VG1 and VG2 may be about 2V.

If the voltage VG1 is less than the voltage VG2, i.e., the end 106-1 of the gate electrode layer 120 is connected to lower voltage and the end 106-2 of the gate electrode layer 120 is connected to higher voltage, the gate electrode layer 120 shifts to the right, as shown in FIG. 2B. This is because such voltages VG1 and VG2 cause electrons to flow from left to right. Similarly, if the voltage VG1 is greater than the voltage VG2, i.e., the end 106-1 of the gate electrode layer 120 is connected to higher voltage and the end 106-2 of the gate electrode layer 120 is connected to lower voltage, the gate electrode layer 120 shifts to the left, in accordance with some embodiments.

As shown in FIG. 2A, before the programming of the OTP memory cell 102, the gate electrode layer 120 has a thickness T1 from a edge of the end 106-1 of the gate electrode layer 120 to the channel layer 116 in the X-direction, and a thickness T2 from a edge of the end 106-2 of the gate electrode layer 120 to the channel layer 116 in the X-direction. In some embodiments, the thickness T1 is equal to the thickness T2, as shown in FIG. 2A. After the programming of the OTP memory cell 102, the thickness T1 of the gate electrode layer 120 is changed into the thickness T1′ and the thickness T2 of the gate electrode layer 120 is changed into the thickness T2′. The thickness T1′ is different to the thickness T2′.

In the case of the voltage VG1 (connected to end 106-1) is less than the voltage VG2 (connected to end 106-2) during the programming, the thickness T1′ is less than the thickness T2′ after the programming, as shown in FIG. 2B. In other words, the thickness T1 is reduced into the thickness T1′ and the thickness T2 is increased into the thickness T2′. Similarly, in the case of the voltage VG1 (connected to end 106-1) is greater than the voltage VG2 (connected to end 106-2) during the programming, the thickness T1′ is greater than the thickness T2′ after the programming. Furthermore, a top surface of the gate electrode layer 120 is non-planar after the programming of the of the OTP memory cell 102. In some embodiments, the gate electrode layer 120 has a sloped top surface after the programming of the of the OTP memory cell 102, as shown in FIG. 2B.

In some embodiments, the thickness T1 or T2 of the gate electrode layer 120 before the programming is reduced into zero (0) after the programming. For example, after the programming that the voltage VG1 (connected to end 106-1) is less than the voltage VG2 (connected to end 106-2), the thickness T1′ of the gate electrode layer 120 is zero, as shown in FIG. 2C. In such embodiments, the edge of the end 106-1 of the gate electrode layer 120 is aligned with a sidewall of the channel layer 116 after the programming, as shown in FIG. 2C.

Due to such location and shape change of the gate electrode layer 120, the gate control of the gate structure 106 is changed. Therefore, the threshold voltage of the transistor 103 in OTP memory cell 102 of the OTP memory device 100 is also changed. More specifically, the OTP memory device 100 (specifically, the transistor 103 in OTP memory cell 102) has a first threshold voltage (may be referred to as threshold voltage Vth1) before the programming, and a second threshold voltage (may be referred to as threshold voltage Vth1′), which is different to the first threshold voltage, after the programming. As such, according to the read current of the transistor 103 in OTP memory cell 102 (from one source/drain region 104sd to the other source/drain region 104sd passing through the channel layer 116) during the OTP memory cell 102 is read, it can be known whether the OTP memory cell 102 has been programmed.

In a read operation of the OTP memory device 100, in order to read the OTP memory cell 102, the end 106-1 and the end 106-2 of the gate structure 106 (specifically, the gate electrode layer 120) are connected to a voltage about 0V or slightly greater than 0V (through the gate contact 110), one of the source/drain regions 104sd (through the source/drain contact 108) is connected to 0V, and the other one of the source/drain regions 104sd (through the source/drain contact 108) is connected to the supply voltage V_{DD} (greater than 0V), such that a read current of the transistor 103 in the OTP memory cell 102 is generated. If the OTP memory cell 102 is not programmed, i.e., the location and shape of the gate electrode layer 120 maintain that shown in FIG. 2A and the transistor 103 still has the threshold voltage Vth1 discussed above, a first read current of the transistor 103 in the OTP memory cell 102 (may be referred to as current Iread1) is read. If the OTP memory cell 102 has been programmed, i.e., the location and shape of the gate electrode layer 120 are changed into that shown in FIG. 2B or FIG. 2C and the transistor 103 has the threshold voltage Vth1′ discussed above, a second read current of the transistor 103 in the OTP memory cell 102 (may be referred to as current Iread1′) is read.

As discussed above, due to the threshold voltage Vth1 of the transistor 103 in the OTP memory cell 102 before the programming and the threshold voltage Vth1′ of the transistor 103 in the OTP memory cell 102 after the programming are different, the current Iread1 of the transistor 103 in the OTP memory cell 102 before the programming is different to the current Iread1′ after the programming are different. Therefore, according to the current value of the read current of the transistor 103 in the OTP memory cell 102, the logic state of the OTP memory cell 102 can be known. For example, if the read current of the transistor 103 in the OTP memory cell 102 is greater than 5 μA, the logic state of the OTP memory cell 102 is at the logic state “0”, and if the read current of the transistor 103 in the OTP memory cell 102 is less than 10 nA, the logic state of the OTP memory cell 102 is at the logic state “1”.

The OTP memory cell 102 discussed above shows the FinFET structure. In some embodiments, the transistor 103 in the OTP memory cell 102 may be a gate-all-around (GAA) transistor. FIG. 3A illustrates an X-Z cross-sectional view of the OTP memory device 100 with the OTP memory cell 102 having a GAA structure along the line A-A′ of FIG. 1 before the OTP memory device 100 is programmed, in accordance with some embodiments of the present disclosure. The OTP memory cell 102 shown in FIG. 3A is similar to the OTP memory cell 102 shown in FIG. 2A, except that the OTP memory cell 102 includes more channel layers to construct the GAA structure. As shown in FIG. 3A, the OTP memory cell 102 includes channel layers 116-1′, 116-2′, and 116-3′ (may be collectively referred to as channel layers 116′). The channel layers 116′ are suspended over the substrate 112 and stacked in the Z-direction. More specifically, the channel layer 116-1′ is over and separated from the substrate 112 in the Z-direction, the channel layer 116-2′ is over and separated from the channel layer 116-1′ in the Z-direction, and the channel layer 116-3′ is over and separated from the channel layer 116-2′ in the Z-direction, as shown in FIG. 3A. In some embodiments, three channel layers 116-1′, 116-2′, and 116-3′ are vertically stacked (or vertically arranged) from each other in the Z-direction for the transistor 103 in the OTP memory cell 102. However, there may be another appropriate number of nanostructures in one transistor. For example, there may be from 2 to 10 channel layers 116′ in the transistor 103 in the OTP memory cell 102.

Similar to the discussion in above, the gate structure 106 wraps and/or surrounds suspended, vertically stacked channel layers 116′ in the channel region 104ch of the active region 104. More specifically, the gate dielectric layer 118 of the gate structure 106 wraps around each of the channel layer 116′ and the gate electrode layer 120 of the gate structure 106 wraps around the gate dielectric layer 118 and each of the channel layer 116′, as shown in FIG. 3A.

Similarly, the OTP memory device 100 with the OTP memory cell 102 having the GAA structure shown in FIG. 3A is not programmed, in accordance with some embodiments of the present disclosure. FIG. 3B illustrates an X-Z cross-sectional view of the OTP memory device 100 with the OTP memory cell 102 having the GAA structure along the line A-A′ of FIG. 1 after the OTP memory device 100 is programmed, in accordance with some embodiments of the present disclosure. FIG. 3C illustrates an X-Z cross-sectional view of the OTP memory device 100 with the OTP memory cell 102 having the GAA structure along the line A-A′ of FIG. 1 after the OTP memory device 100 is programmed, in accordance with some embodiments of the present disclosure.

Similarly, in order to program the OTP memory cell 102, the end 106-1 and the end 106-2 of the gate structure 106 (specifically, the gate electrode layer 120) are respectively connected to different voltages. In other words, in the program operation of the OTP memory device 100, the end 106-1 of the gate electrode layer 120 is connected to the voltage VG1 discussed above and the end 106-2 of the gate electrode layer 120 is connected to the voltage VG2 discussed above, such that a program current is generated along the gate structure 106 (specifically, the gate electrode layer 120). Furthermore, the source/drain contacts 108 are floating during the programming of the OTP memory cell 102.

After the ends 106-1 and 106-2 are respectively connected to the voltages VG1 and VG2 and the source/drain contacts 108 are floating, the gate electrode layer 120 is also changed, as shown in FIG. 3B. Compare to original gate electrode layer 120 (shown as dash line), the shape and the location of the gate electrode layer 120 are also changed. As discussed above, the voltage difference between the voltages VG1 and VG2 induce electromigration to make the shape and the location of the gate electrode layer 120 are changed. Similarly, if the voltage VG1 is less than the voltage VG2, the gate electrode layer 120 shifts to the right, as shown in FIG. 3B. If the voltage VG1 is greater than the voltage VG2, the gate electrode layer 120 shifts to the left, in accordance with some embodiments.

As shown in FIG. 3A, before the programming of the OTP memory cell 102, the gate electrode layer 120 has a thickness T3 from the edge of the end 106-1 of the gate electrode layer 120 to the channel layers 116′ in the X-direction, and a thickness T4 from the edge of the end 106-2 of the gate electrode layer 120 to the channel layers 116′ in the X-direction. In some embodiments, the thickness T3 is equal to the thickness T4, as shown in FIG. 3A. After the programming of the OTP memory cell 102, the thickness T3 of the gate electrode layer 120 is changed into the thickness T3′ and the thickness T4 of the gate electrode layer 120 is changed into the thickness T4′.

In the case of the voltage VG1 is less than the voltage VG2 during the programming, the thickness T3′ is less than the thickness T4′ after the programming, as shown in FIG. 3B. In other words, the thickness T3 is reduced into the thickness T3′ and the thickness T4 is increased into the thickness T4′. Similarly, in the case of the voltage VG1 is greater than the voltage VG2 during the programming, the thickness T3′ is greater than the thickness T4′ after the programming. Similarly, the top surface of the gate electrode layer 120 is non-planar after the programming of the of the OTP memory cell 102, as discussed above. In some embodiments, the gate electrode layer 120 has the sloped top surface after the programming of the of the OTP memory cell 102, as shown in FIG. 3B.

Similarly, in some embodiments, the thickness T3 or T4 of the gate electrode layer 120 before the programming is reduced into zero (0) after the programming. For example, after the programming that the voltage VG1 is less than the voltage VG2, the thickness T3′ of the gate electrode layer 120 is zero, as shown in FIG. 3C. In such embodiments, the edge of the end 106-1 of the gate electrode layer 120 is aligned with a sidewall of the channel layer 116′ after the programming, as shown in FIG. 3C.

Similarly, the gate control of the gate structure 106 is changed due to such location and shape change of the gate electrode layer 120. Therefore, the OTP memory device 100 (specifically, the transistor 103 in OTP memory cell 102) has the threshold voltage Vth1 before the programming as discussed above and the threshold voltage Vth1′ after the programming as discussed above. As such, according to the read current of the transistor 103 in the OTP memory cell 102 during the OTP transistor 102 is read, it can be known whether the OTP transistor 102 has been programmed.

Similarly, in the read operation of the OTP memory device 100, in order to read the OTP memory cell 102, the end 106-1 or the end 106-2 of the gate structure 106 (specifically, the gate electrode layer 120) is connected to a voltage about 0V or slightly greater than 0V (through the gate contact 110) and one of the source/drain regions 104sd (through the source/drain contact 108) is connected to 0V and the other one of the source/drain regions 104sd (through the source/drain contact 108) is connected to the supply voltage V_{DD}, such that a read current of the transistor 103 in the OTP memory cell 102 is generated. If the OTP memory cell 102 is not programmed, i.e., the location and shape of the gate electrode layer 120 maintain that shown in FIG. 3A and the transistor 103 still has the threshold voltage Vth1 discussed above, the current Iread1 of the transistor 103 in the OTP memory cell 102 discussed above is read. If the OTP memory cell 102 has been programmed, i.e., the location and shape of the gate electrode layer 120 are changed into that shown in FIG. 3B or FIG. 3C and the transistor 103 has the threshold voltage Vth1′ discussed above, the current Iread1′ of the transistor 103 in the OTP memory cell 102 discussed above is read.

Similarly, due to the threshold voltage Vth1 of the transistor 103 in the OTP memory cell 102 before the programming and the threshold voltage Vth1′ of the transistor 103 in the OTP memory cell 102 after the programming are different, the current Iread1 of the transistor 103 in the OTP memory cell 102 before the programming is different to the current Iread1′ after the programming are different. Therefore, according to the current value of the read current of the transistor 103 in the OTP memory cell 102, the logic state of the OTP memory cell 102 can be known. For example, if the read current of the transistor 103 in the OTP memory cell 102 is greater than 5 μA, the logic state of the OTP memory cell 102 is at the logic state “0”, and if the read current of the transistor 103 in the OTP memory cell 102 is less than 10 nA, the logic state of the OTP memory cell 102 is at the logic state “1”.

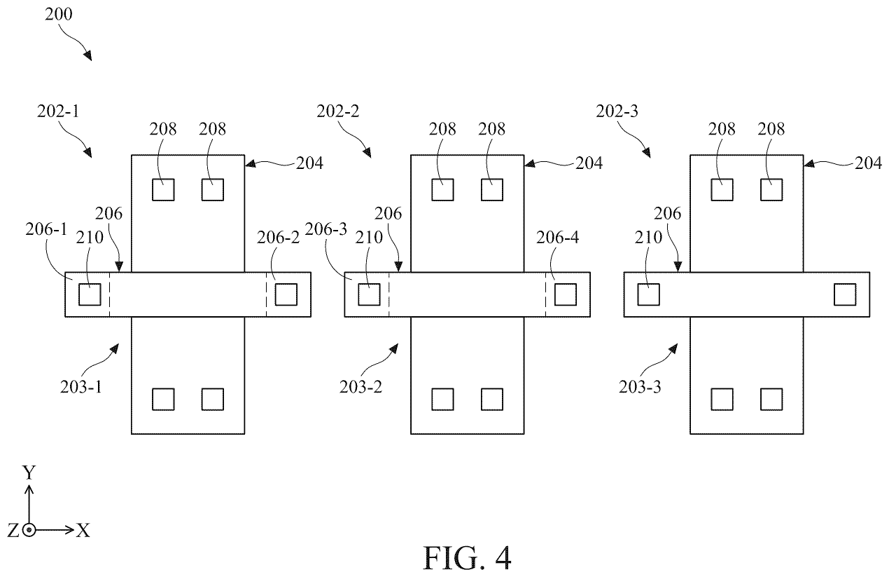

FIG. 4 illustrates a top view (or a layout) of an OTP memory device 200 with multiple OTP memory cells 202-1 to 202-3 (may be collectively referred to as OTP memory cells 202), in accordance with some alternative embodiments of the present disclosure. In some embodiments, each of the OTP memory cells 202-1 to 202-3 is similar to the OTP memory cell 102 discussed above. The OTP memory cells 202-1 to 202-3 respectively include the transistors 203-1, 203-2, and 203-3 (may be collectively referred to as transistors 203), which are similar to the transistor 103 discussed above.

Similarly, as shown in FIG. 4, each of the OTP memory cells 202-1 to 202-3 include an active region 204, a gate structure 206, source/drain contacts 208, and gate contacts 210, which are respectively similar to the active region 104, the gate structure 106, the source/drain contacts 108, and the gate contacts 110 discussed above. As shown in FIG. 4, the OTP memory cells 202-1 to 202-3 are arranged in the X-direction. Therefore, the active regions 204 of the OTP memory cells 202-1 to 202-3 are also arranged in the X-direction. Furthermore, the gate structures 206 of the OTP memory cells 202-1 to 202-3 are also arranged and aligned with each other in the X-direction. Although the OTP memory device 200 shown in FIG. 4 includes three OTP memory cells 202-1 to 202-3, it should be noted that the OTP memory device 200 may include more OTP memory cells similar to the OTP memory cells 202 arranged in the X-direction, in accordance with some embodiments. The other features as well as programming and reading mechanism of the OTP memory cells 202-1 to 202-3 are also similar to the OTP memory cell 102 discussed above and will not repeatedly discuss herein.

The difference between the OTP memory cell 102 and the OTP memory cells 202-1 to 202-3 is how to determine whether the OTP memory cell is programmed. As discussed above, it can determine that whether the OTP memory cell 102 is programmed according to the current value of the read current of the transistor 103 in the OTP memory cell 102, thereby determining the logic state of the OTP memory cell 102.

In the embodiments shown in FIG. 4, one of the OTP memory cells 202-1 to 202-3 is selected to serve as reference cell. For example, the OTP memory cell 202-1 serve as reference cell, in accordance with some embodiments. Such OTP memory cell 202-1 will not be programmed (i.e., the OTP memory cell 202-1 always has the threshold voltage Vth1 discussed above) and will be compared with the other selected OTP memory cells 202 (i.e., the OTP memory cells 202-2 and 202-3) to obtain the logic state of the OTP memory cells 202 (i.e., the OTP memory cells 202-2 and 202-3). In other words, only one of the OTP memory cells 202-2 and 202-3 will be selected at a time. If the OTP memory cell 202-2 is selected, the OTP memory cell 202-1 will be compared with the OTP memory cell 202-2, and if the OTP memory cell 202-3 is selected, the OTP memory cell 202-1 will be compared with memory cell 202-3. For example, if the other selected OTP memory cell 202-2 or 202-3 have been programmed (in the way discussed above), the OTP memory cell 202-2 or 202-3 has the threshold voltage Vth1′ different to the threshold voltage Vth1, and the read current of the transistor 203-2 or 203-3 in the selected OTP memory cell 202-2 or 202-3 would be different from the read current of the transistor 203-1 in the OTP memory cell 202-1 during reading (in the way discussed above). In other words, the current difference between the read current of the selected transistor 203-2 or 203-3 and the read current of the transistor 203-1 would be greater than a first predetermined threshold difference (e.g., in a range from 1×10⁻¹⁰ A to 1×10⁻⁶ A). If the selected OTP memory cell 202-2 or 202-3 are not programmed (the OTP memory cell 202-2 or 202-3 still has the threshold voltage Vth1 discussed above), the read current of the transistor 203-2 or 203-3 in the selected OTP memory cell 202-2 or 202-3 would be substantially the same as the read current of the transistor 203-1 in the OTP memory cell 202-1 during reading (in the way discussed above). In other words, the current difference between the read current of the selected transistor 203-2 or 203-3 and the read current of the transistor 203-1 would be less than the first predetermined threshold difference. Therefore, according to comparison, the logic state of the OTP memory cells 202 (which not used as reference cell) can be known.

For example, in a read operation of the OTP memory device 200, the OTP memory cell 202-1 serve as reference cell, in order to read the OTP memory cell 202-2, the end 206-1 and the end 206-2 of the gate structure 206 (specifically, the gate electrode layer 120) of the OTP memory cell 202-1 and the end 206-3 and the end 206-4 of the gate structure 206 (specifically, the gate electrode layer 120) of the OTP memory cell 202-2 are connected to a voltage about 0V or slightly greater than 0V (through the gate contact 210), one of the source/drain regions 104sd (through the source/drain contact 208) of the OTP memory cell 202-1 is connected to 0V, the other one of the source/drain regions 104sd (through the source/drain contact 208) of the OTP memory cell 202-1 is connected to the supply voltage V_{DD}, one of the source/drain regions 104sd (through the source/drain contact 208) of the OTP memory cell 202-2 is connected to 0V, the other one of the source/drain regions 104sd (through the source/drain contact 208) of the OTP memory cell 202-2 is connected to the supply voltage V_{DD}, such that a read current of the transistor 203-1 in the OTP memory cell 202-1 and a read current of the transistor 203-2 in the OTP memory cell 202-2 are generated. According to the difference between the read current of the transistor 203-2 and the read current of the transistor 203-1 (greater or less than the first predetermined threshold difference), the logic state of the OTP memory cells 202-2 (which not used as reference cell) can be known.

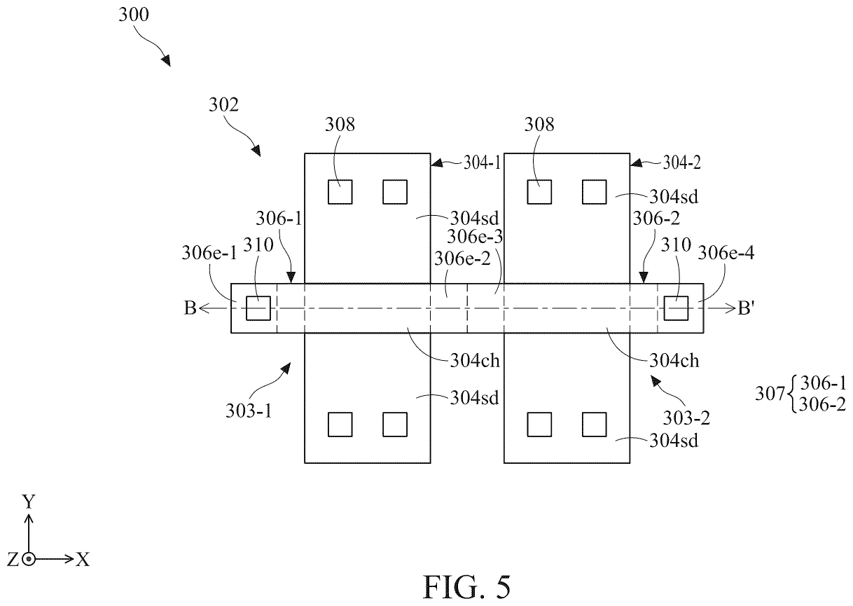

FIG. 5 illustrates a top view (or a layout) of an OTP memory device 300 with an OTP memory cell 302, in accordance with some alternative embodiments of the present disclosure. Although the OTP memory device 300 shown in FIG. 5 includes one OTP memory cell 302, it should be noted that the OTP memory device 300 may include more OTP memory cells similar to the OTP memory cell 302 arranged in rows and columns into an OTP memory array, in accordance with some embodiments.

The OTP memory cell 302 is similar to the OTP memory cell 102 discussed above, except that the OTP memory cell 302 is constructed by two transistors 303-1 and 303-2 (may be collectively referred to as transistors 303). Therefore, the OTP memory cell 302 includes an active region 304-1 for the transistors 303-1 and an active region 304-2 for the transistors 303-2 (may be collectively referred to as active region 304), which extend lengthwise in the Y-direction. The active regions 304 each also includes a channel region 304ch and source/drain regions 304sd. Similarly, the source/drain regions 304sd are disposed on opposite sides of the channel regions 304ch in the Y-direction, in accordance with some embodiments.

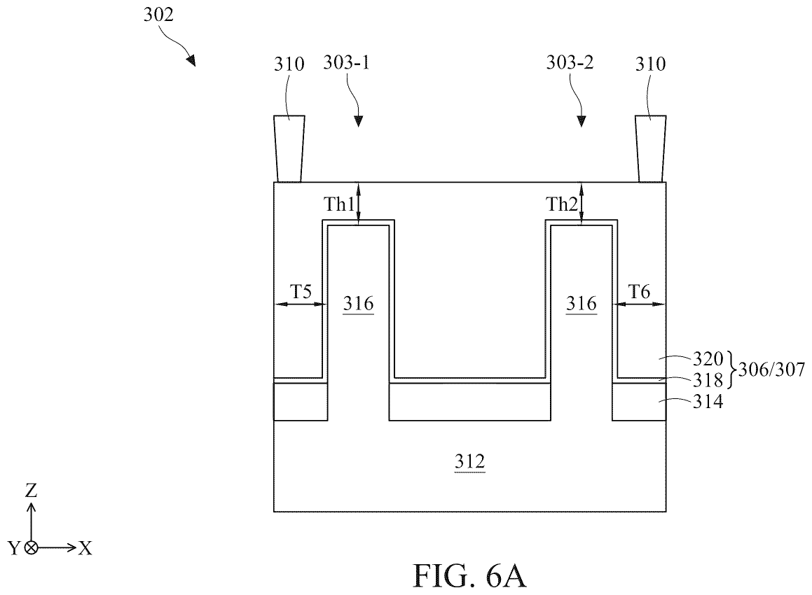

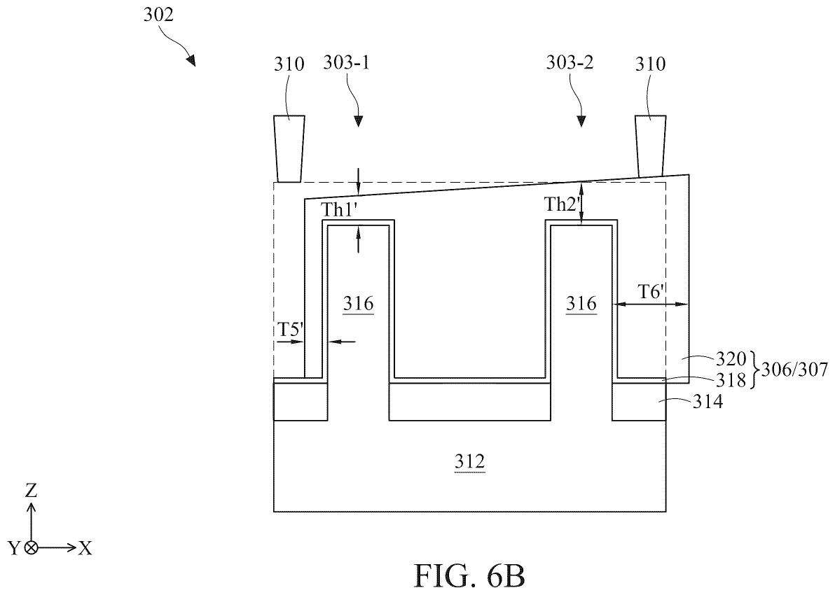

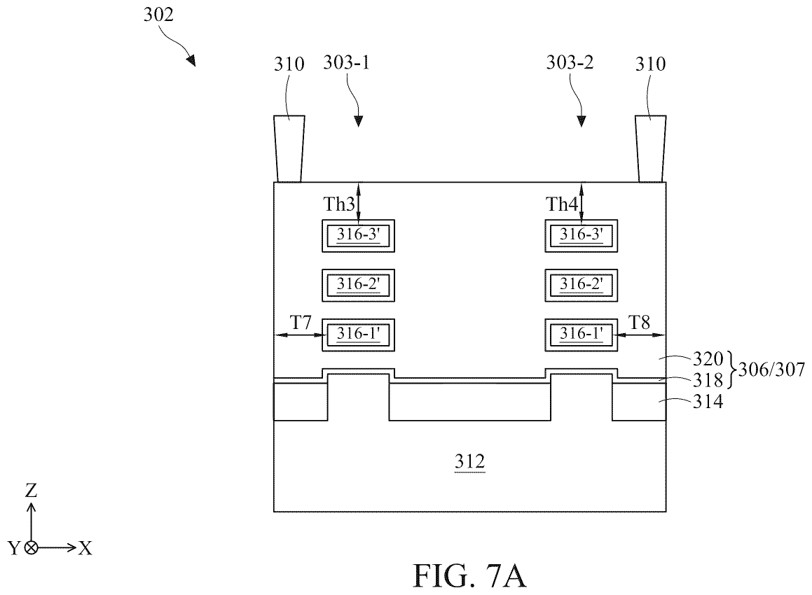

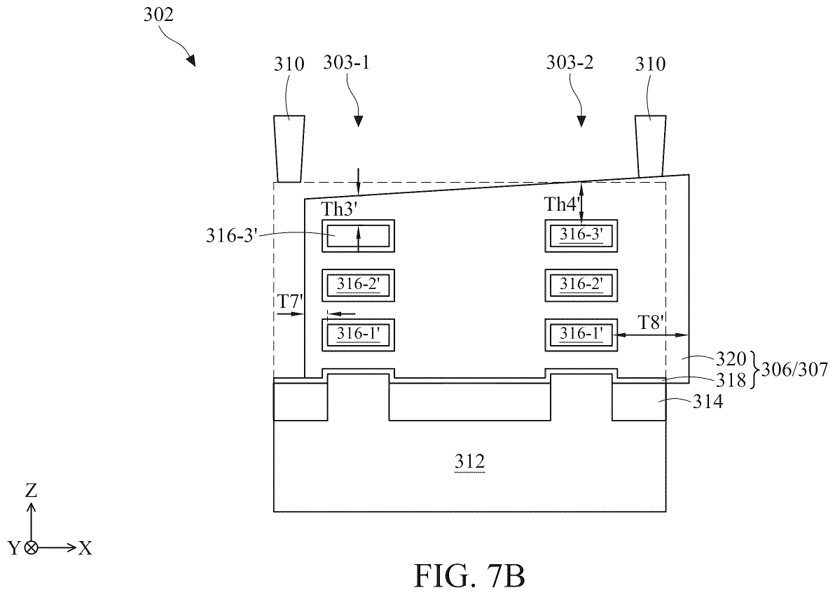

The OTP memory cell 302 further includes gate structures 306-1 and 306-2 (may be collectively referred to as gate structures 306). The gate structures 306 extend lengthwise in the X-direction to cross the active regions 304, as shown in FIG. 5. Similar to the gate structure 106 discussed above, the gate structures 306-1 and 306-2 are respectively disposed over the channel region 304ch of the respective active region 304 (i.e., the channel layer(s) 316 shown in FIGS. 6A to 7B) and disposed between respective source/drain regions 304sd of the active region 304 (i.e., source/drain features in source/drain regions 304sd (not shown)). Therefore, the active regions 304 and the gate structures 306 are configured to provide the transistors 303-1 and 303-2 for the OTP memory cell 302. Furthermore, it is noted that the gate structures 306-1 and 306-2 are in contact with each other in the X-direction. More specifically, as shown in FIG. 5, the gate structure 306-1 has ends 306e-1 and 306e-2 on opposite sides of the gate structure 306-1 (the gate electrode layer 320 of the gate structure 306-1) in the X-direction and the gate structure 306-2 has ends 306e-3 and 306e-4 on opposite sides of the gate structure 306-2 (the gate electrode layer 320 of the gate structure 306-2) in the X-direction, in which the end 306e-2 of the gate structure 306-1 (the gate electrode layer 320 of the gate structure 306-1) is in contact with the end 306e-3 of the gate structure 306-2 (the gate electrode layer 320 of the gate structure 306-2) in the X-direction.

In some embodiments, the gate structures 306-1 and 306-2 are formed simultaneously. In some aspects, the gate structures 306-1 and 306-2 may be considered together as one gate structure, such as a gate structure 307, as shown in FIG. 5. In some embodiments, the gate structure 307 is a common gate structure and shared by the transistors 303-1 and 303-2 for the OTP memory cell 302.

Similarly, the OTP memory cell 302 further includes source/drain contacts 308 and gate contacts 310. As shown in FIG. 5, the source/drain contacts 308 are disposed on the source/drain regions 304sd of the active regions 304, over and electrically connected to the source/drain features (not shown) in the source/drain regions 304sd. The gate contacts 310 are disposed on and electrically connected to the gate structures 306 (the gate structure 307). More specifically, the gate contacts 310 are disposed on the end 306e-1 of the gate structure 306-1 and 306e-4 of the gate structure 306-2 (or the ends 306e-1 and 306e-4 of the gate structure 307), as shown in FIG. 5. In some embodiments, the material of the source/drain contacts 308 is the same as that discussed above for the source/drain contacts 108.

In some embodiments, the transistors 303 in the OTP memory cell 302 may be fin field-effect transistors (FinFETs). FIG. 6A illustrates an X-Z cross-sectional view of the OTP memory device 300 with the OTP memory cell 302 having FinFET structures along a line B-B′ of FIG. 5 before the OTP memory device 300 is programmed, in accordance with some embodiments of the present disclosure. As shown in FIG. 5, the OTP memory cell 302 further includes a substrate 312 and isolation features 314 similar to the substrate 112 and the isolation features 114 discussed above, the detail will not repeatedly discuss herein.

As shown in FIGS. 5 and 6A, in the case of the transistors 303 in the OTP memory cell 302 are FinFETs, the OTP memory cell 302 further includes channel layers 316 in the channel regions 304ch of the active regions 304. More specifically, each of the transistors 303-1 and 303-2 in the OTP memory cell 302 has one channel layer although there may be another appropriate number of nanostructures in one transistor 303 in the OTP memory cell 302. For example, there may be from 2 to 3 channel layers 316 in one transistor 303. As the channel layer 116 discussed above, the channel layers 316 are over and protruded from the substrate 312, in accordance with some embodiments. Furthermore, the channel layers 316 extend in the Z-direction from the substrate 312. In some embodiments, the channel layer 316 is between the isolation features 314 in the X-direction, as shown in FIG. 6A. In some aspects, the isolation features 314 are around the channel layers 316. In some embodiments, the channel layers 316 are formed from the substrate 312. In some embodiments, the material of the channel layers 316 is the same as that discussed above for the channel layers 116.

As shown in FIGS. 5 and 6A, the gate structure 306-1 engage the active region 304-1 to construct the transistor 303-1 and the gate structure 306-2 engage the active region 304-2 to construct the transistor 303-2. In some aspects, the gate structure 307 engages the active regions 304-1 and 304-2 to construct the transistors 303-1 and 303-2. The gate structure 306-1 wraps around the channel layer 316 in the channel region 304ch of the active region 304-1 and the gate structure 306-2 wraps around the channel layer 316 in the channel region 304ch of the active region 304-2. In some aspects, the gate structure 307 wraps around the channel layers 316 in the channel regions 304ch of the active regions 304-1 and 304-2. The gate structure 307 (including the gate structures 306-1 and 306-2) has a gate dielectric layer 318 and a gate electrode layer 320. The gate dielectric layer 318 wraps around the channel layers 316 and the gate electrode layer 320 wraps around the gate dielectric layer 318 and the channel layers 316. More specifically, the gate dielectric layer 318 is on top surfaces and sidewalls of the channel layers 316, as shown in FIG. 6A. In some embodiments, the material of the gate dielectric layer 318 and the gate electrode layer 320 is the same as that discussed above for the gate dielectric layer 118 and the gate electrode layer 120.

As shown in FIG. 6A, the gate contacts 310 are over and electrically connected to the gate electrode layer 320 of the gate structures 306, in accordance with some embodiments. Furthermore, the gate contacts 310 are disposed on the end 306e-1 of the gate structure 306-1 and the end 306e-4 of the gate structure 306-2, as shown in FIG. 5. In some aspects, the ends 306e-1 and 306e-4 may also represent the ends of the gate structure 307. In other words, the gate contacts 310 are disposed on the ends 306e-1 and 306e-4 of the gate structure 307, in accordance with some embodiments. In some embodiments, the ends 306e-1 and 306e-4 of the gate structures 306 may also represent the ends of the gate electrode layer 320. In other words, the gate contacts 310 are disposed on the ends 306e-1 and 306e-4 of the gate electrode layer 320, as shown in FIGS. 5 and 6A.

Similar to the source/drain regions 104sd discussed above, the source/drain regions 304sd of the OTP memory cell 302 includes source/drain features. The source/drain features in the source/drain regions 304sd are disposed on opposite sides of the respective gate structure 306 in the Y-direction to form the transistors 303 in the OTP memory cell 302. The source/drain features may also be referred to as source/drains. In some embodiments, source/drain feature(s) may refer to a source or a drain, individually or collectively dependent upon the context. In some embodiments, the material of the source/drain features is as the above discussion.

The OTP memory device 300 with the OTP memory cell 302 having the FinFET structures shown in FIG. 6A is not programmed, in accordance with some embodiments of the present disclosure. FIG. 6B illustrates an X-Z cross-sectional view of the OTP memory device 300 with the OTP memory cell 302 having the FinFET structures along the line B-B′ of FIG. 5 after the OTP memory device 300 is programmed, in accordance with some embodiments of the present disclosure.

Similar to the programming of the OTP memory cell 102 discussed above, the end 306e-1 and the end 306e-4 of the gate structures 306 (specifically, the gate electrode layer 320) are respectively connected to different voltages. The end 306e-1 of the gate electrode layer 320 is connected to the voltage VG1 discussed above and the end 306e-4 of the gate electrode layer 320 is connected to the voltage VG2 discussed above, through the gate contacts 310, such that a program current is generated along the gate structures 306 (specifically, the gate electrode layer 320). Furthermore, the source/drain contacts 308 are floating during the programming of the OTP memory cell 302.

After the ends 306e-1 and 306e-4 are respectively connected to the voltages VG1 and VG2 and the source/drain contacts 308 are floating, the gate electrode layer 320 is changed, as shown in FIG. 6B. Compare to original gate electrode layer 320 (shown as dash line), the shape and the location of the gate electrode layer 320 are changed. As discussed above, the voltage difference between the voltages VG1 and VG2 induce electromigration to make the shape and the location of the gate electrode layer 320 are changed. Similarly, if the voltage VG1 is less than the voltage VG2, the gate electrode layer 320 shifts to the right, as shown in FIG. 6B. If the voltage VG1 is greater than the voltage VG2, the gate electrode layer 320 shifts to the left, in accordance with some embodiments.

As shown in FIG. 6A, before the programming of the OTP memory cell 302, the gate electrode layer 320 has a thickness T5 from a edge of the end 306e-1 of the gate electrode layer 320 to the channel layer 316 of the transistor 303-1 in the X-direction, and a thickness T6 from a edge of the end 306e-4 of the gate electrode layer 320 to the channel layer 316 of the transistor 303-2 in the X-direction. In some embodiments, the thickness T5 is equal to the thickness T6, as shown in FIG. 6A. After the programming of the OTP memory cell 302, the thickness T5 of the gate electrode layer 320 is changed into the thickness T5′ and the thickness T6 of the gate electrode layer 320 is changed into the thickness T6′.

In the case of the voltage VG1 is less than the voltage VG2 during the programming, the thickness T5′ is less than the thickness T6′ after the programming, as shown in FIG. 6B. In other words, the thickness T5 is reduced into the thickness T5′ and the thickness T6 is increased into the thickness T6′. Similarly, in the case of the voltage VG1 is greater than the voltage VG2 during the programming, the thickness T5′ is greater than the thickness T6′ after the programming. Furthermore, a top surface of the gate electrode layer 320 is non-planar after the programming of the of the OTP memory cell 302. In some embodiments, the gate electrode layer 320 has a sloped top surface after the programming of the of the OTP memory cell 302, as shown in FIG. 6B. In some embodiments, the thickness T5 or T6 of the gate electrode layer 320 before the programming is reduced into zero (0) after the programming (i.e., the thickness T5′ or the thickness T6′ is zero (0)).

Furthermore, as shown in FIG. 6A, before the programming of the OTP memory cell 302, the gate electrode layer 320 has a thickness Th1 from a top surface of the channel layer 316 of the transistor 303-1 to the top surface of the gate electrode layer 320 in the Z-direction, and a thickness Th2 from a top surface of the channel layer 316 of the transistor 303-2 to the top surface of the gate electrode layer 320 in the Z-direction. In some embodiments, the thickness Th1 is equal to the thickness Th2, as shown in FIG. 6A. After the programming of the OTP memory cell 302, the thickness Th1 of the gate electrode layer 320 is changed into the thickness Th1′ and the thickness Th2 of the gate electrode layer 320 is changed into the thickness Th2′.

In the case of the voltage VG1 is less than the voltage VG2 during the programming, the thickness Th1′ is less than the thickness Th2′ after the programming, as shown in FIG. 6B. In other words, the thickness Th1 is reduced into the thickness Th1′ and the thickness Th2 is increased into the thickness Th2′. Similarly, in the case of the voltage VG1 is greater than the voltage VG2 during the programming, the thickness Th1′ is greater than the thickness Th2′ after the programming.

Due to such location and shape change of the gate electrode layer 320, the gate control of the gate structures 306 (or the gate structure 307) is changed. Therefore, the threshold voltages of the transistors 303-1 and 303-2 in OTP memory cell 302 are is also changed. More specifically, the transistor 303-1 has a third threshold voltage (may be referred to as threshold voltage Vth2) and the transistor 303-2 has a fourth threshold voltage (may be referred to as threshold voltage Vth3) before the programming. After the programming of the OTP memory cell 302, the transistor 303-1 has a fifth threshold voltage (may be referred to as threshold voltage Vth2′) and the transistor 303-2 has a sixth threshold voltage (may be referred to as threshold voltage Vth3′). In some embodiments, the threshold voltage Vth2 of the transistor 303-1 and the threshold voltage Vth3 of the transistor 303-2 before the programming are the same. As such, according to the read currents of the transistors 303-1 and 303-2 in OTP memory cell 302 during the OTP memory cell 302 is read, it can be known whether the OTP memory cell 302 has been programmed.

In a read operation of the OTP memory device 300, in order to read the OTP memory cell 302, the end 306e-1 or the end 306e-4 of the gate structures 306 (the gate structure 307) (specifically, the gate electrode layer 320) are connected to a voltage about 0V or slightly greater than 0V, one of the source/drain regions 304sd of the active region 304-1 is connected to 0V and the other one of the source/drain regions 304sd of the active region 304-1 is connected to the supply voltage V_{DD}, and one of the source/drain regions 304sd of the active region 304-2 is connected to 0V and the other one of the source/drain regions 304sd of the active region 304-2 is connected to the supply voltage V_{DD}, such that read currents of the transistors 303-1 and 303-2 in the OTP memory cell 302 are generated. If the OTP memory cell 302 is not programmed and the transistors 303-1 still has the threshold voltage Vth2 discussed above and the transistors 303-2 still has the threshold voltage Vth3 discussed above, i.e., the location and shape of the gate electrode layer 320 maintain that shown in FIG. 6A, a third read current of the transistor 303-1 in the OTP memory cell 302 (may be referred to as current Iread2) and a fourth read current of the transistor 303-2 in the OTP memory cell 302 (may be referred to as current Iread3) are read. If the OTP memory cell 302 has been programmed, i.e., the location and shape of the gate electrode layer 320 are changed into that shown in FIG. 6B and the transistors 303-1 has the threshold voltage Vth2′ discussed above and the transistors 303-2 has the threshold voltage Vth3′ discussed above, a fifth read current of the transistor 303-1 in the OTP memory cell 302 (may be referred to as current Iread2′) and a sixth read current of the transistor 303-2 in the OTP memory cell 302 (may be referred to as current Iread3′) are read.

As discussed above, the threshold voltage Vth2 of the transistor 303-1 and the threshold voltage Vth3 of the transistor 303-2 before the programming are the same, and the threshold voltage Vth2′ of the transistor 303-1 and the threshold voltage Vth3′ of the transistor 303-2 after the programming are different. As such, if the OTP memory cell 302 has been programmed, the read current of the transistor 303-1 in the OTP memory cell 302 would be different from the read current of the transistor 303-2 in the OTP memory cell 302 during reading (i.e., a current difference between the read current of the transistor 303-1 and the read current of the transistor 303-2 would be greater than a second predetermined threshold difference (e.g., in a range from 1×10⁻¹⁰ A to 1×10⁻⁶ A)). If the OTP memory cell 302 is not programmed (the transistors 303-1 still has the threshold voltage Vth2 discussed above and the transistors 303-2 still has the threshold voltage Vth3 discussed above), the read current of the transistor 303-1 in the OTP memory cell 302 would be substantially the same as the read current of the transistor 303-2 in the OTP memory cell 302 during reading (i.e., the current difference between the read current of the transistor 303-1 and the read current of the transistor 303-2 would be less than the second predetermined threshold difference).

Therefore, according to comparison, the logic state of the OTP memory cell 302 can be known. For example, if the read current of the transistor 303-1 in the OTP memory cell 302 is different from the read current of the transistors 303-2 in the transistor 303-2 in the OTP memory cell 302, the logic state of the OTP memory cells 302 are at the logic state “0”, and if the read current of the transistor 303-1 in the OTP memory cell 302 is substantially equal to the read current of the transistors 303-2 in the OTP memory cell 302, the logic state of the OTP memory cell 302 are at the logic state “1”.

The OTP memory cell 302 discussed above shows the FinFET structure. In some embodiments, the transistors 303-1 and 303-2 in the OTP memory cell 302 may be a gate-all-around (GAA) transistor. FIG. 7A illustrates an X-Z cross-sectional view of the OTP memory device 300 with the OTP memory cell 302 having GAA structures along the line B-B′ of FIG. 5 before the OTP memory device 300 is programmed, in accordance with some embodiments of the present disclosure. The OTP memory cell 302 shown in FIG. 7A is similar to the OTP memory cell 302 shown in FIG. 6A, except that the OTP memory cell 302 includes more channel layers to construct the GAA structure. As shown in FIG. 7A, each of the transistors 303-1 and 303-2 in the OTP memory cell 302 includes channel layers 316-1′, 316-2′, and 316-3′ (may be collectively referred to as channel layers 316′). The channel layers 316′ are suspended over the substrate 312 and stacked in the Z-direction.

Similar to the discussion in above, the gate structure 306 wraps and/or surrounds suspended, vertically stacked channel layers 316′ in the channel region 304ch of the active regions 304. More specifically, the gate dielectric layer 318 of the gate structures 306 (the gate structure 307) wraps around each of the channel layer 316′ and the gate electrode layer 320 of the gate structures 106 (the gate structure 307) wraps around the gate dielectric layer 318 and each of the channel layer 316′, as shown in FIG. 7A.

Similarly, the OTP memory device 300 with the OTP memory cell 302 having the GAA structures shown in FIG. 7A is not programmed, in accordance with some embodiments of the present disclosure. FIG. 7B illustrates an X-Z cross-sectional view of the OTP memory device 300 with the OTP memory cell 302 having the GAA structures along the line B-B′ of FIG. 5 after the OTP memory device 300 is programmed, in accordance with some embodiments of the present disclosure.

Similarly, in a program operation of the OTP memory device 300, in order to program the OTP memory cell 302, the end 306e-1 and the end 306e-4 of the gate structures 306 (specifically, the gate electrode layer 320) are respectively connected to different voltages. The end 306e-1 of the gate electrode layer 320 is connected to the voltage VG1 discussed above and the end 306e-4 of the gate electrode layer 320 is connected to the voltage VG2 discussed above, through the gate contacts 310, such that a program current is generated along the gate structure 306 (specifically, the gate electrode layer 320). Furthermore, the source/drain contacts 308 are floating during the programming of the OTP memory cell 302.

After the ends 306e-1 and 306e-4 are respectively connected to the voltages VG1 and VG2 and the source/drain contacts 308 are floating, the gate electrode layer 320 is changed, as shown in FIG. 7B. Compare to original gate electrode layer 320 (shown as dash line), the shape and the location of the gate electrode layer 320 are also changed. As discussed above, the voltage difference between the voltages VG1 and VG2 induce electromigration to make the shape and the location of the gate electrode layer 320 are changed. Similarly, if the voltage VG1 is less than the voltage VG2, the gate electrode layer 320 shifts to the right, as shown in FIG. 7B. If the voltage VG1 is greater than the voltage VG2, the gate electrode layer 320 shifts to the left, in accordance with some embodiments.

As shown in FIG. 7A, before the programming of the OTP memory cell 302, the gate electrode layer 320 has a thickness T7 from the edge of the end 306e-1 of the gate electrode layer 320 to the channel layers 316′ of the transistor 303-1 in the X-direction, and a thickness T8 from the edge of the end 306e-4 of the gate electrode layer 320 to the channel layers 316′ of the transistor 303-2 in the X-direction. In some embodiments, the thickness T7 is equal to the thickness T8, as shown in FIG. 7A. After the programming of the OTP memory cell 302, the thickness T7 of the gate electrode layer 320 is changed into the thickness T7′ and the thickness T8 of the gate electrode layer 320 is changed into the thickness T8′.

In the case of the voltage VG1 is less than the voltage VG2 during the programming, the thickness T7′ is less than the thickness T8′ after the programming, as shown in FIG. 7B. In other words, the thickness T7 is reduced into the thickness T7′ and the thickness T8 is increased into the thickness T8′. Similarly, in the case of the voltage VG1 is greater than the voltage VG2 during the programming, the thickness T7′ is greater than the thickness T8′ after the programming. Similarly, the top surface of the gate electrode layer 320 is non-planar after the programming of the of the OTP memory cell 302. In some embodiments, the gate electrode layer 320 has the sloped top surface after the programming of the of the OTP memory cell 302, as shown in FIG. 7B. In some embodiments, the thickness T7 or T8 of the gate electrode layer 320 before the programming is reduced into zero (0) after the programming (i.e., the thickness T7′ or the thickness T8′ is zero (0)).

Furthermore, as shown in FIG. 7A, before the programming of the OTP memory cell 302, the gate electrode layer 320 has a thickness Th3 from a topmost surface of the channel layers 316′ of the transistor 303-1 to the top surface of the gate electrode layer 320 in the Z-direction, and a thickness Th4 from a topmost surface of the channel layers 316′ of the transistor 303-2 to the top surface of the gate electrode layer 320 in the Z-direction. In some embodiments, the thickness Th3 is equal to the thickness Th4, as shown in FIG. 7A. After the programming of the OTP memory cell 302, the thickness Th3 of the gate electrode layer 320 is changed into the thickness Th3′ and the thickness Th4 of the gate electrode layer 320 is changed into the thickness Th4′.

In the case of the voltage VG1 is less than the voltage VG2 during the programming, the thickness Th3′ is less than the thickness Th4′ after the programming, as shown in FIG. 7B. In other words, the thickness Th3 is reduced into the thickness Th3′ and the thickness Th4 is increased into the thickness Th4′. Similarly, in the case of the voltage VG1 is greater than the voltage VG2 during the programming, the thickness Th3′ is greater than the thickness Th4′ after the programming.

Similarly, the gate control of the gate structures 306 (or the gate structure 307) is changed due to such location and shape change of the gate electrode layer 320. Therefore, the transistor 303-1 has the threshold voltage Vth2 and the transistor 303-2 has the threshold voltage Vth3 before the programming, as discussed above. In some embodiments, the threshold voltage Vth2 of the transistor 303-1 and the threshold voltage Vth3 of the transistor 303-2 before the programming are the same. After the programming of the OTP memory cell 302, the transistor 303-1 has the threshold voltage Vth2′ and the transistor 303-2 has the threshold voltage Vth3′, as discussed above. As such, according to the read currents of the transistors 303-1 and 303-2 in OTP memory cell 302 during the OTP memory cell 302 is read, it can be known whether the OTP memory cell 302 has been programmed.

Similarly, in the read operation of the OTP memory device 300, in order to read the OTP memory cell 302, the end 306e-1 or the end 306e-4 of the gate structures 306 (the gate structure 307) (specifically, the gate electrode layer 320) are connected to a voltage about 0V or slightly greater than 0V, one of the source/drain regions 304sd of the active region 304-1 is connected to 0V and the other one of the source/drain regions 304sd of the active region 304-1 is connected to the supply voltage V_{DD}, and one of the source/drain regions 304sd of the active region 304-2 is connected to 0V and the other one of the source/drain regions 304sd of the active region 304-2 is connected to the supply voltage V_{DD}, such that read currents of the transistors 303-1 and 303-2 in the OTP memory cell 302 are generated. If the OTP memory cell 302 is not programmed, i.e., the location and shape of the gate electrode layer 320 maintain that shown in FIG. 7A and the transistors 303-1 still has the threshold voltage Vth2 discussed above and the transistors 303-2 still has the threshold voltage Vth3 discussed above, the current Iread2 of the transistor 303-1 and the current Iread3 of the transistor 303-2 in the OTP memory cell 302 discussed above is read. If the OTP memory cell 302 has been programmed, i.e., the location and shape of the gate electrode layer 320 are changed into that shown in FIG. 7B and the transistors 303-1 has the threshold voltage Vth2′ discussed above and the transistors 303-2 has the threshold voltage Vth3′ discussed above, the current Iread2′ of the transistor 303-1 and the current Iread3′ of the transistor 303-2 in the OTP memory cell 302 discussed above is read.

Similarly, the threshold voltage Vth2 of the transistor 303-1 and the threshold voltage Vth3 of the transistor 303-2 before the programming are the same, and the threshold voltage Vth2′ of the transistor 303-1 and the threshold voltage Vth3′ of the transistor 303-2 after the programming are different. As such, if the OTP memory cell 302 has been programmed, the read current of the transistor 303-1 in the OTP memory cell 302 would be different from the read current of the transistor 303-2 in the OTP memory cell 302 during reading. If the OTP memory cell 302 is not programmed, the read current of the transistor 303-1 in the OTP memory cell 302 would be substantially the same as the read current of the transistor 303-2 in the OTP memory cell 302 during reading.

Therefore, according to comparison, the logic state of the OTP memory cell 302 can be known. For example, if the read current of the transistor 303-1 in the OTP memory cell 302 is different from the read current of the transistors 303-2 in the OTP memory cell 302, the logic state of the OTP memory cells 302 are at the logic state “0”, and if the read current of the transistor 303-1 in the OTP memory cell 302 is substantially equal to the read current of the transistors 303-2 in the OTP memory cell 302, the logic state of the OTP memory cell 302 are at the logic state “1”.

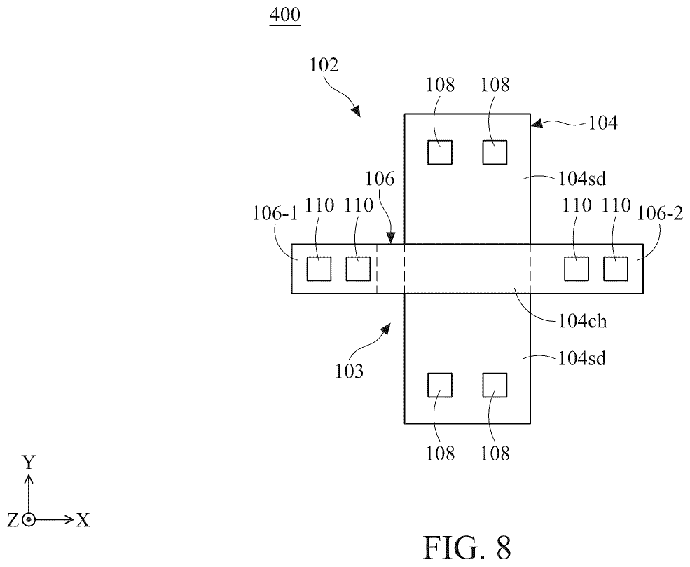

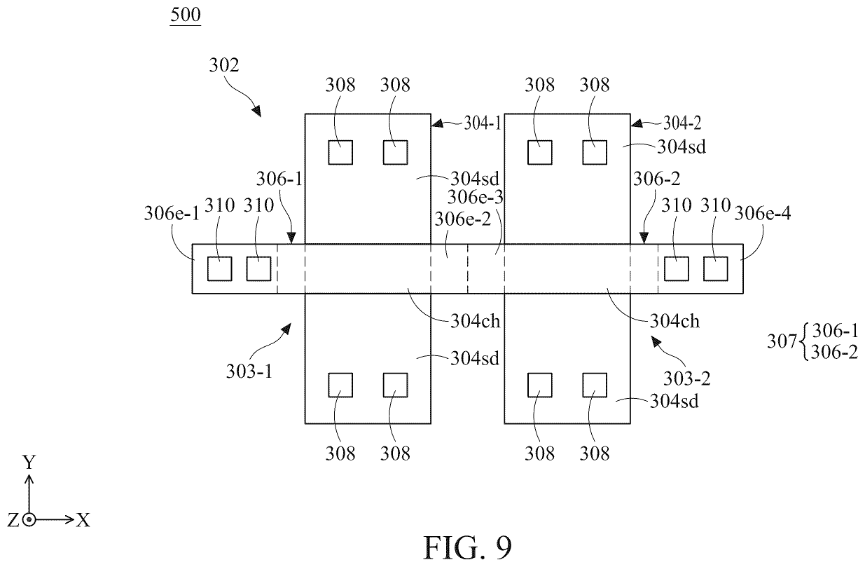

FIGS. 8 and 9 illustrate top views (or layouts) of OTP memory devices 400 and 500, in accordance with some alternative embodiments of the present disclosure. The OTP memory devices 400 and 500 shown in FIGS. 8 and 9 are similar to the OTP memory devices 100 and 300 shown in FIGS. 1 and 5, except that there are more gate contacts disposed on ends of the gate structure (the gate electrode layer). As shown in FIG. 8, in order to enhance the electro-migration effect, each of the ends 106-1 and 106-2 of the gate structure 106 (the gate electrode layer 120) of the OTP memory cell 102 may include at least two gate contacts 110. More specifically, two gate contacts 110 are over and electrically connected to the end 106-1 of the gate structure 106 (the gate electrode layer 120) and other two gate contacts 110 are over and electrically connected to the end 106-2 of the gate structure 106 (the gate electrode layer 120). The two gate contacts 110 over the end 106-1 of the gate structure 106 are together connected to the voltage VG1 discussed above and the other two gate contacts 110 over the end 106-2 of the gate structure 106 are together connected to the voltage VG2 discussed above. As such, the ends 106-1 of the gate structure 106 is connected to the voltage VG1 through two gate contacts 110 and the ends 106-2 of the gate structure 106 is connected to the voltage VG2 through two gate contacts 110.

Similarly, as shown in FIG. 9, each of the ends 306e-1 and 306e-4 of the gate structures 306 (the gate electrode layer 320) of the OTP memory cell 302 includes two gate contacts 310. The two gate contacts 310 over the end 306e-1 of the gate structure 306-1 are together connected to the voltage VG1 discussed above and the other two gate contacts 310 over the end 306e-4 of the gate structure 306-2 are together connected to the voltage VG2 discussed above. As such, the ends 306e-1 of the gate structure 306-1 is connected to the voltage VG1 through two gate contacts 310 and the ends 306e-4 of the gate structure 306-2 is connected to the voltage VG2 through two gate contacts 310.

The embodiments of the present disclosure offer advantages over existing art, though it should be understood that other embodiments may offer different advantages, not all advantages are necessarily discussed herein, and that no particular advantage is required for all embodiments. For example, embodiments discussed herein include OTP memory devices with OTP memory cell with FinFET or GAA structure(s). The OTP memory cell is programmed by electromigration mechanism, such that the OTP memory cell may be constructed by one or two transistors, thereby resulting the OTP memory cell with low footprint/area penalty. Furthermore, the OTP memory cell can be programmed at a relatively low voltage than conventional OTP memory cell due to the electromigration mechanism for programming. Therefore, the power consumption of the OTP memory cell is improved.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A one-time-programmable (OTP) memory device, comprising:
a first active region, comprising:
a first channel region having a first channel layer; and
first source/drain regions disposed on opposite sides of the first channel region in a Y-direction, wherein the first source/drain regions have first source/drain features electrically connected to the first channel layer;
a first gate dielectric layer wrapping around the first channel layer; and
a first gate electrode layer extending in an X-direction and wrapping around the first channel layer and the first gate dielectric layer,
wherein a first thickness of the first gate electrode layer from a first edge of a first end of the first gate electrode layer to the first channel layer in the X-direction is equal to a second thickness of the first gate electrode layer from a second edge of a second end of the first gate electrode layer to the first channel layer in the X-direction, and a logic state of the OTP memory device is at a first logic state;
wherein in a first program operation of the OTP memory device, after the first end is connected to a first voltage and the second end is connected to a second voltage different to the first voltage, the first thickness is different to the second thickness, and the logic state of the OTP memory device is at a second logic state different to the first logic state.

2. The OTP memory device as claimed in claim 1,
wherein the first voltage is less than the second voltage,
wherein after the first end is connected to the first voltage and the second end is connected to the second voltage, the first thickness is less than the second thickness.

3. The OTP memory device as claimed in claim 1, wherein in a read operation of the OTP memory device, the first end and the second end are connected to 0V, one of the first source/drain regions is connected to 0V, and the other one of the first source/drain regions is connected to a supply voltage higher than 0V.

4. The OTP memory device as claimed in claim 1, wherein the OTP memory device has a first threshold voltage before the first end is connected to the first voltage and the second end is connected to the second voltage, and a second threshold voltage different to the first threshold voltage after the first end is connected to the first voltage and the second end is connected to the second voltage.

5. The OTP memory device as claimed in claim 1, further comprising:
a second active region arranged with the first active region in the X-direction, comprising:
a second channel region having a second channel layer; and
second source/drain regions disposed on opposite sides of the second channel region in the Y-direction, wherein the second source/drain regions have second source/drain features electrically connected to the second channel layer;
a second gate dielectric layer wrapping around the second channel layer; and
a second gate electrode layer extending in the X-direction and wrapping around the second channel layer and the second gate dielectric layer,
wherein a third thickness of the second gate electrode layer from a third edge of a third end of the second gate electrode layer to the second channel layer in the X-direction is equal to the first thickness before the first end is connected to the first voltage and the second end is connected to the second voltage,
wherein a fourth thickness of the second gate electrode layer from a fourth edge of a fourth end of the second gate electrode layer to the second channel layer in the X-direction is equal to the second thickness before the first end is connected to the first voltage and the second end is connected to the second voltage,
wherein after the first end is connected to the first voltage and the second end is connected to the second voltage, the first thickness is different to the third thickness and the second thickness is different to the fourth thickness.

6. The OTP memory device as claimed in claim 5, wherein in a read operation of the OTP memory device, the first end, the second end, the third end, and the fourth end are connected to 0V, one of the first source/drain regions is connected to 0V, and the other one of the first source/drain regions is connected to a supply voltage higher than 0V, one of the second source/drain regions is connected to 0V, and the other one of the second source/drain regions is connected to the supply voltage.

7. The OTP memory device as claimed in claim 1, further comprising:
a second active region arranged with the first active region in the X-direction, comprising:
a second channel region having a second channel layer; and
second source/drain regions disposed on opposite sides of the second channel region in the Y-direction, wherein the second source/drain regions have second source/drain features electrically connected to the second channel layer;
a second gate dielectric layer wrapping around the second channel layer; and
a second gate electrode layer extending in the X-direction and wrapping around the second channel layer and the second gate dielectric layer,
wherein the second gate electrode layer has a third end and a fourth end on opposite sides of the second gate electrode layer in the X-direction, the third end of the second gate electrode layer is in contact with the second end of the first gate electrode layer in the X-direction,
wherein before a second program operation of the OTP memory device, the first thickness is equal to a third thickness of the second gate electrode layer from a third edge of the fourth end of the second gate electrode layer to the second channel layer in the X-direction,
wherein in the second program operation of the OTP memory device, after the first end is connected to the first voltage and the fourth end is connected to the second voltage, the first thickness is different to the third thickness, and the logic state of the OTP memory device is at the second logic state.

8. The OTP memory device as claimed in claim 1, further comprising:
a first gate contact and a second gate contact over the first end of the first gate electrode layer; and
a third gate contact and a fourth gate contact over the second end of the first gate electrode layer,
wherein the first end is connected to the first voltage through the first gate contact and the second gate contact, and the second end is connected to the second voltage through the third gate contact and the fourth gate contact.

9. The OTP memory device as claimed in claim 1, wherein the first channel layer is over and protrudes from a substrate in a Z-direction.

10. The OTP memory device as claimed in claim 1, wherein the first channel layer is over and separated from a substrate in a Z-direction, wherein the first active region further comprises a second channel layer over and separated from the first channel layer in the Z-direction.

11. The OTP memory device as claimed in claim 1, wherein the first edge of the first end of the first gate electrode layer is aligned with a sidewall of the first channel layer after the first end is connected to the first voltage and the second end is connected to the second voltage.

12. A one-time-programmable (OTP) memory device, comprising:
a first memory cell, comprising:
a first active region, comprising:
a first channel region having a first channel layer; and
first source/drain regions disposed on opposite sides of the first channel region in a Y-direction, wherein the first source/drain regions have first source/drain features electrically connected to the first channel layer; and
a first gate structure extending in an X-direction and engaging the first active region to construct a first transistor,
wherein before a first program operation of the OTP memory device, the first transistor has a first threshold voltage and a logic state of the OTP memory device is at a first logic state,
wherein in the first program operation of the OTP memory device, a first end of the first gate structure is connected to a first voltage and a second end of the first gate structure is connected to a second voltage different to the first voltage, such that a program current is generated along the first gate structure,
wherein a voltage difference between the first voltage and the second voltage is greater than an electromigration threshold,
wherein after the first program operation of the OTP memory device, the first transistor has a second threshold voltage different to the first threshold voltage, and the logic state of the OTP memory device is at a second logic state different to the first logic state.

13. The OTP memory device as claimed in claim 12, wherein in a read operation of the OTP memory device, the first end and the second end are connected to 0V, one of the first source/drain regions is connected to 0V, and the other one of the first source/drain regions is connected to a supply voltage higher than 0V.

14. The OTP memory device as claimed in claim 12, further comprising:
a first gate contact and a second gate contact over the first end of the first gate structure; and
a third gate contact and a fourth gate contact over the second end of the first gate structure,
wherein the first end is connected to the first voltage through the first gate contact and the second gate contact, and the second end is connected to the second voltage through the third gate contact and the fourth gate contact.

15. The OTP memory device as claimed in claim 12, further comprising:
a second memory cell, comprising:
a second active region arranged with the first active region in the X-direction, comprising:
a second channel region having a second channel layer; and
second source/drain regions disposed on opposite sides of the second channel region in the Y-direction, wherein the second source/drain regions have second source/drain features electrically connected to the second channel layer; and
a second gate structure extending in the X-direction and engaging the second active region to construct a second transistor,
wherein before the first program operation of the OTP memory device, the second transistor has the first threshold voltage,
wherein after the first program operation of the OTP memory device, the second transistor has the first threshold voltage different to the second threshold voltage of the first transistor.

16. The OTP memory device as claimed in claim 15, wherein in a read operation of the OTP memory device, the first end and the second end are connected to 0V, a third end and a fourth end of the second gate structure are connected to 0V, one of the first source/drain regions is connected to 0V, and the other one of the first source/drain regions is connected to a supply voltage higher than 0V, one of the second source/drain regions is connected to 0V, and the other one of the second source/drain regions is connected to the supply voltage.

17. The OTP memory device as claimed in claim 12, wherein the first memory cell further comprises:
a second active region arranged with the first active region in the X-direction, comprising:
a second channel region having a second channel layer; and
second source/drain regions disposed on opposite sides of the second channel region in the Y-direction, wherein the second source/drain regions have second source/drain features electrically connected to the second channel layer; and
a second gate structure extending in the X-direction and engaging the second active region to construct a second transistor,
wherein the second gate structure has a third end and a fourth end on opposite sides of the second gate structure in the X-direction, the third end of the second gate structure is in contact with the second end of the first gate structure in the X-direction,
wherein before a second program operation of the OTP memory device, the first transistor has a third threshold voltage and the second transistor has a fourth threshold voltage, the third threshold voltage and the fourth threshold voltage are the same, and the logic state of the OTP memory device is at the first logic state,
wherein in the second program operation of the OTP memory device, the first end of the first gate structure is connected to the first voltage and the fourth end of the second gate structure is connected to the second voltage different to the first voltage, such that a program current is generated along the first gate structure and the second gate structure,
wherein after the second program operation of the OTP memory device, the first transistor has a fifth threshold voltage different to the third threshold voltage, the second transistor has a sixth threshold voltage different to the fourth threshold voltage and the fifth threshold voltage, and the logic state of the OTP memory device is at the second logic state different to the first logic state.

18. The OTP memory device as claimed in claim 12, wherein the first channel layer is over and protrudes from a substrate in a Z-direction.

19. The OTP memory device as claimed in claim 12, wherein the first channel layer is over and separated from a substrate in a Z-direction, wherein the first active region further comprises a second channel layer over and separated from the first channel layer in the Z-direction.

20. The OTP memory device as claimed in claim 12, wherein the first gate structure comprises a first gate dielectric layer wrapping around the first channel layer and a first gate electrode layer extending in the X-direction and wrapping around the first channel layer and the first gate dielectric layer, and a first edge of the first gate electrode layer is aligned with a sidewall of the first channel layer after the first end of the first gate structure is connected to the first voltage and the second end of the first gate structure is connected to the second voltage.
